(19) United States
(12) Patent Application Publication
(10) Pub. No.: US 2008/0158817 A1
(43) Pub. Date: Jul. 3, 2008

(54) ELECTRONIC APPARATUS

(75) Inventors: Yosuke TSUNODA, Kawasaki (JP); Masumi SUZUKI, Kawasaki (JP); Michimasa AOKI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 12/042,882

(22) Filed: Mar. 5, 2008

(30) Foreign Application Priority Data
Sep. 6, 2005 (JP) PCT/JP2005/016314

(51) Int. Cl. H05K 7/20; F28D 15/00

(52) U.S. Cl. 361/697; 165/104.33; 361/687; 165/80.3; 165/80.4; 165/185; 62/259.2; 361/709

(57) ABSTRACT

An electronic apparatus 100 includes a heat-generating element 1, a heat-radiating plate 4 which is used in heat radiation of the heat-generating element, and a housing 10 which accommodates the heat-generating element and the heat-radiating plate. The heat-radiating plate is disposed between the heat-generating element and a first wall portion 10a of the housing, and a support stage 5 for forming an air layer is disposed between the heat-radiating plate and the first wall portion. Since the heat-insulating effect of the air layer prevents the heat diffused from the heat-radiating plate from being easily conducted to the first wall portion, the formation of a heat spot in the first wall portion can be avoided even when the heat-generating element which generates a large amount of heat is used.

This application is a continuation of PCT International No. PCT/JP2005/016314, filed on 6 Sep. 2005, which is hereby incorporated by reference herein in its entirety as if fully set forth herein.

### BACKGROUND OF THE INVENTION

The present invention relates to an electronic apparatus which includes a heat-generating element such as an LSI in a housing.

Electronic apparatuses such as laptop computers and cellular phones have been increasingly reduced in thickness and size, while there is a growing tendency for those apparatuses to generate more heat from electronic components such as LSIs included therein. For such heat-generating components, a cooling method has conventionally been employed which uses a heat sink (heat-radiating plate), a cooling fan or the like.

A heat-radiating plate is formed of a material with high thermal conductivity and diffuses heat from a heat-generating component to perform heat radiation. However, it is necessary to prevent such a situation that the heat radiated from the heat-radiating plate increases the temperature of a housing of an electronic apparatus, especially at a portion where a user touches with his hand (for example, a portion where operation buttons are placed), resulting in user discomfort.

To address this, Japanese Patent Laid-Open No. 2001-350546 discloses a heat-radiating configuration in which a heat-radiating plate and a vacuum heat-insulating material are placed one on another between a heat-generating component and an apparatus case to radiate heat from the heat-generating component and to prevent an increase in temperature of the case at the same time.

Japanese Patent Laid-Open No. 2002-319652 and Japanese Patent Laid-Open No. 2003-8956 disclose a heat-radiating configuration in which a heat-conducting member, a heat-radiating plate (Japanese Patent Laid-Open No. 2003-8956), and a heat-insulating member are placed one on another and sandwiched between a heat-generating component and a housing or an exterior cover to radiate heat from the heat-generating component and also to prevent heat conduction to a portion of the housing or the cover where a human body touches.

Japanese Patent Laid-Open No. 10(1998)-229287 discloses a heat-radiating configuration in which heat from a heat-generating component is transmitted to a housing by using a heat-diffusing sheet to perform heat radiation. Japanese Patent Laid-Open No. 10(1998)-229287 also proposes a configuration in which a box-shaped support frame (spacer) is placed between a portion of the heat-diffusing sheet immediately below the heat-generating component and the housing to provide a heat-insulating layer of air to prevent a local increase in temperature of a portion of the housing immediately below the heat-generating component.

In the heat-radiating configurations disclosed in Japanese Patent Laid-Open No. 2001-350546, Japanese Patent Laid-Open No. 2002-319652, and Japanese Patent Laid-Open No. 2003-8956, a heat-insulating member 207 placed over a heat-radiating plate 204 and a heat-conducting member 206 is basically in contact with a housing 210 as shown in FIG. 19. Thus, when the amount of heat generated from a heat-generating component 201 is increased, the heat conducted through the heat-insulating member 207 is then conducted to the housing 210 to increase the temperature of the housing 210.

Particularly, a general center P of the area of the housing 210 overlying the heat-generating component 201 when viewed from a direction in which the heat-generating component 201, the heat-radiating plate 204, the heat-conducting member 206, and the heat-insulating member 207 are placed over the housing 201 is likely to be a heat spot at a significantly higher temperature than in the surroundings.

According to the heat-radiating configuration disclosed in Japanese Patent Laid-Open No. 10(1998)-229287, the air heat-insulating layer is provided between the heat-diffusing sheet and the housing to allow prevention of a local increase in temperature within the area of the housing overlying the heat-generating component. However, a local increase in temperature may arise in a portion of the area without the air heat-insulating layer close to the heat-generating component (for example, a portion adjacent to the support frame where the heat-diffusing sheet is in direct contact with the housing).

It is an object of the present invention to provide an electronic apparatus having a heat-radiating configuration which can radiate heat efficiently even with a heat-generating member generating a large amount of heat and can prevent formation of a heat spot in a housing.

### BRIEF SUMMARY OF THE INVENTION

An electronic apparatus as one aspect of the present invention includes a heat-generating element, a heat-radiating plate which is used in heat radiation of the heat-generating element, and a housing which accommodates the heat-generating element and the heat-radiating plate. The heat-radiating plate is disposed between the heat-generating element and a first wall portion of the housing, the electronic apparatus further comprises a support stage for forming an air layer between the heat-radiating plate and the first wall portion.

This can prevent the heat diffused from the heat-radiating plate from being easily conducted to the first wall portion by the heat-insulating effect of the air layer. Therefore, the formation of a heat spot in the first wall portion can be avoided even when the heat-generating element which generates a large amount of heat is used.

A heat-insulating member may be placed closer to the first wall portion than the heat-radiating plate and the air layer may be formed between the heat-insulating member and the first wall portion. This can prevent the formation of the heat spot more effectively by combining the heat-insulating effect of the heat-insulating member and the air layer. The heat-insulating effect by the air layer can be sufficiently obtained when the air layer has a thickness of at least half of a thickness of the heat-insulating member.

It is preferable that the air layer is opened to space other than the air layer in the housing. This can avoid the formation of the heat spot more effectively by diffusing the heat conducted to the air layer from the heat-radiating plate or the heat-insulating member into the space in the housing.

It is preferable that the support stage is formed of a fibrous material, a foam material, or a stacked material including a heat-insulating member therein. These materials can prevent the heat from being easily conducted to the first wall portion via the support stage since they have lower thermal conductivity.

It is preferable that the support stage is disposed outside an area where the heat-generating element is placed (an area that overlies the heat-generating element) when viewed from a direction in which the heat-generating element and the heat-radiating plate are disposed one on another. This can prevent the heat from being easily conducted into the first wall portion via the support stage more effectively. For example, a plurality of the support stages spaced from each other may be disposed outside the heat-generating-element-placed area, or the support stage may be formed in a rectangular frame shape surrounding the heat-generating-element-placed area.

The support stage may have elasticity and bring the heat-radiating plate into press contact with the heat-generating element by elastic force. This can reduce the thermal resistance between the heat-generating element and the heat-radiating plate and achieve the heat radiation more efficiently.

A portion of the heat-radiating plate that is in contact with the heat-generating element may be protruded toward the heat-generating element from the remaining portion of the heat-radiating plate. This can dispose another electronic component different from the heat-generating element between the heat-radiating plate and the substrate on which the heat-generating element is mounted and is effective in reducing the size of the electronic apparatus. The heat-radiating plate may have elasticity and bring the protruded portion into press contact with the heat-generating element by elastic force. This can reduce the thermal resistance between the heat-generating element and the heat-radiating plate and achieve the heat radiation more efficiently.

A heat spreader having a size larger than that of the heat-generating element may be placed between the heat-generating element and the heat-radiating plate. This can increase the amount of heat to be conducted in the in-plane direction of the heat-radiating plate and achieve the heat radiation with the heat-radiating plate more efficiently.

A substrate on which the heat-generating element is mounted may be used as the heat-radiating plate. This can eliminate the need for a heat-radiating plate different from the substrate and reduce the thickness, size, and weight of the electronic apparatus.

When an operation member operated by a user is placed in the first wall portion, the user can operate the operation member without feeling uncomfortable.

### BRIEF DESCRIPTION OF THE DRAWINGS

FIG. 1A A section view showing the configuration within a housing of a cellular phone which is Embodiment 1 of the present invention.

FIG. 1B A section view showing the effects when a support stage has elasticity in Embodiment 1.

FIG. 2 A plan perspective view showing an example of arrangement of support stages in Embodiment 1.

FIG. 3 A plan perspective view showing another example of arrangement of the support stages in Embodiment 1.

FIG. 4A A schematic diagram showing a fibrous material used in the support stages in Embodiments.

FIG. 4B A schematic diagram showing a foam material used in the support stages in Embodiments.

FIG. 4C A schematic diagram showing a stacked material used in the support stages in Embodiments.

FIG. 5 A section view showing the configuration within a housing of a portable electronic apparatus which is Embodiment 2 of the present invention.

FIG. 6 A section view showing the configuration within a housing of a portable electronic apparatus which is Embodiment 3 of the present invention.

FIG. 7 A section view showing the configuration within a housing of a portable electronic apparatus which is Embodiment 4 of the present invention.

FIG. 8 A section view showing the configuration within a housing of a portable electronic apparatus which is Embodiment 5 of the present invention.

FIG. 9 A section view showing the configuration within a housing of a portable electronic apparatus which is Embodiment 6 of the present invention.

FIG. 10 A section view showing the configuration within a housing of a portable electronic apparatus which is Embodiment 7 of the present invention.

FIG. 11 A section view showing the configuration within a housing of a portable electronic apparatus which is Embodiment 8 of the present invention.

FIG. 12 A schematic diagram showing the configuration of the portable electronic apparatus according to Embodiment 1.

FIG. 13 A schematic diagram showing the configuration of the portable electronic apparatus according to Embodiment 8.

FIG. 14 Diagrams showing an example of experiment in Embodiment 1.

FIG. 15 Diagrams showing an example of experiment in Embodiment 1.

FIG. 16 Diagrams showing an example of experiment in Embodiment 3.

FIG. 17 A diagram showing an example of experiment in Embodiment 3.

FIG. 18 A schematic diagram showing the configuration of a portable electronic apparatus which is Embodiment 9 of the present invention.

FIG. 19 A section view showing the inner configuration of a conventional electronic apparatus.

### DETAILED DESCRIPTION OF THE PREFERRED EMBODIMENTS

Preferred embodiments of the present invention will hereinafter be described with reference to the drawings.

### Embodiment 1

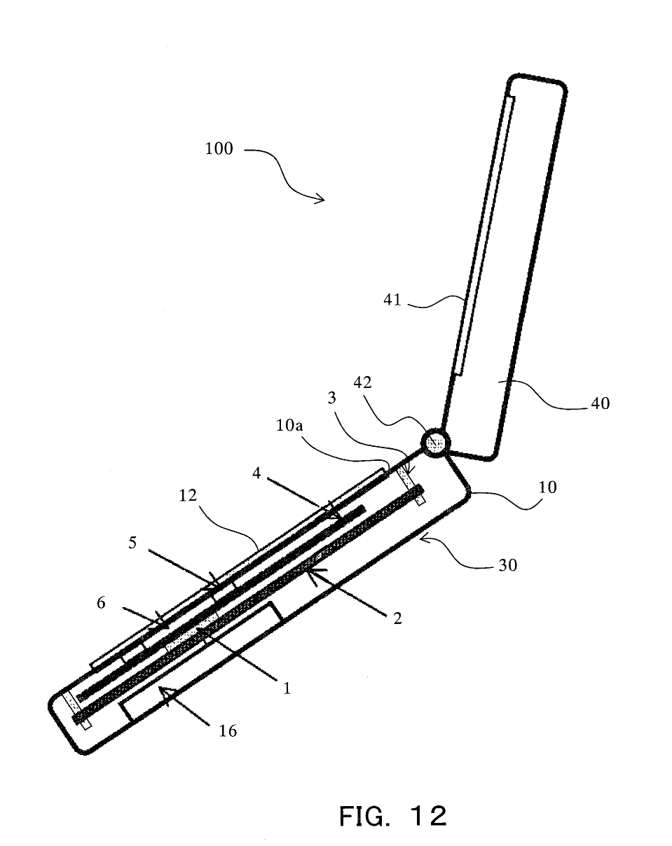

FIG. 12 schematically shows the configuration of a portable electronic apparatus (electronic apparatus) which is Embodiment 1 of the present invention. A portable electronic apparatus 100 of Embodiment 1 has a first body portion 30 and a second body portion 40 which is attached to the first body portion 30 to pivotally open or close about a hinge portion 42.

The first body portion 30 is formed to accommodate a heat-generating element 1, a substrate 2, and a heat-radiating plate 4 in a housing 10 which is a case made of resin such as plastic. A battery 16 is removably put in the housing 10. In the first body portion 30, an operation portion 12 having a keypad and other operation members disposed therein is provided on a housing front-wall 10a which is a front wall portion of the housing 10, that is, a first wall portion. The housing front-wall 10a is not necessary a wall with no opening, and in reality, has a plurality of openings for exposing the operation members.

In the second body portion 40, a display 41 formed of a liquid crystal element or a self-emitting element is provided on a front wall portion of a housing which is a case made of resin such as plastic or metal such as aluminum. The housing contains a circuit (not shown) for driving the display 41.

The heat-generating element 1 is typified by a processing unit such as an LSI and a CPU. However, in the present invention, the heat-generating element includes any electronic component other than the processing unit as long as it generates heat. The basic configuration of the portable electronic apparatus described above applies to Embodiments 2 to 9 described later.

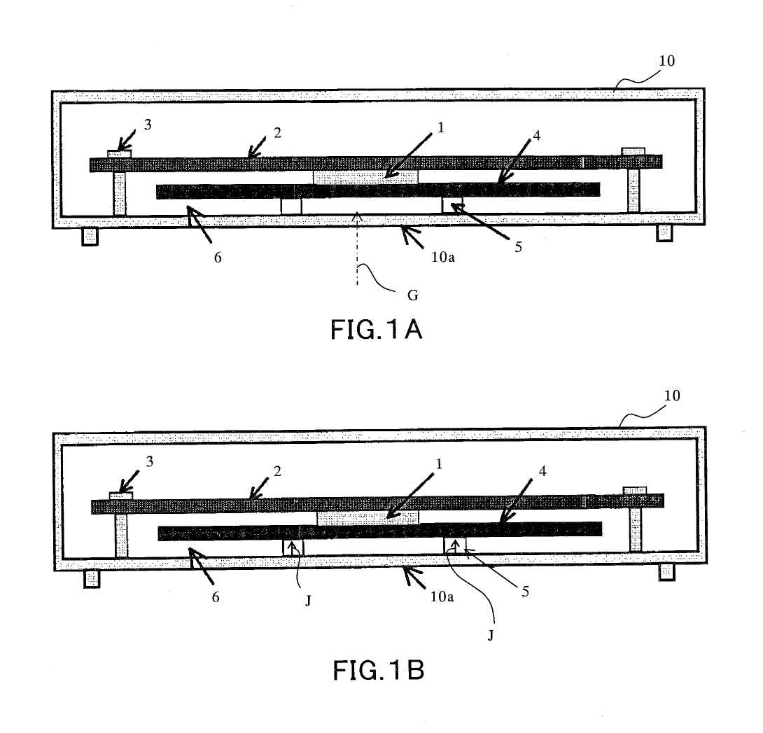

FIG. 1A is an enlarged view of the configuration within the housing 10 forming the first body portion 30. In the view, the housing front-wall 10a is shown at the bottom. This applies to Embodiments 2 to 9 described later.

The heat-generating element 1 is mounted on a surface of the printed board (hereinafter referred to simply as the substrate) 2 closer to the housing front-wall 10a. The heat-generating element 1 and the substrate 2 are placed generally in parallel with the housing front-wall 10. The substrate 2 has a size which extends generally throughout the housing 10 in an in-plane direction. Although not shown, various electronic components other than the heat-generating element 1 are mounted on the substrate 2.

The heat-radiating plate 4 is disposed generally in parallel with the substrate 2 between the heat-generating element 1 and the housing front-wall 10a and is in contact with the heat-generating element 1. The heat-radiating plate 4 radiates heat generated in the heat-generating element 1 by diffusion to cool the heat-generating element 1. The heat-radiating plate 4 is typically made of a metal material with high thermal conductivity such as aluminum (with a thermal conductivity of 200 to 300 W/mK) or copper (thermal conductivity of 300 to 400 W/mK).

The use of a graphite sheet (with thermal conductivity of 200 to 600 W/mK) as the material of the heat-radiating plate 4 can reduce the weight as compared with the use of a metal material. Although not shown, the heat-radiating plate 4 may have a fin shape, for example, for increasing the surface area for heat radiation.

Screws 3 are attached to the substrate 2 at both ends on the left and right. The screws 3 are secured and fixed into screw holes formed in the housing front-wall 10a. In Embodiment 1, support stages 5 are placed between the heat-radiating plate 4 and the housing front-wall 10a to form an air layer 6 having a predetermined thickness between the heat-radiating plate 4 and the housing front-wall 10a. In other words, in Embodiment 1, the support stages 5 (air layer 6), the heat-radiating plate 4, the heat-generating element 1, and the substrate 2 are arranged in the housing 10 in the order from the side of the housing front-wall 10a.

The support stages 5 are sandwiched and fixed between the housing front-wall 10a and the heat-radiating plate 4 subjected to the securing force from the screws 3 via the substrate 2 and the heat-generating element 1. In other words, the support stages 5 have the function of placing the heat-radiating plate 4 spaced from the housing front-wall 10a against the securing force to ensure the air layer 6 having the predetermined thickness. The support stages 5 may be fixed to the housing front-wall 10a or the heat-radiating plate 4 through bonding or a tape.

The heat-radiating plate 4 is formed to have substantially the same size in an in-plane direction as that of the substrate 2 (but to be small enough to avoid interference with the screws 3) in order to maximize heat-radiation efficiency.

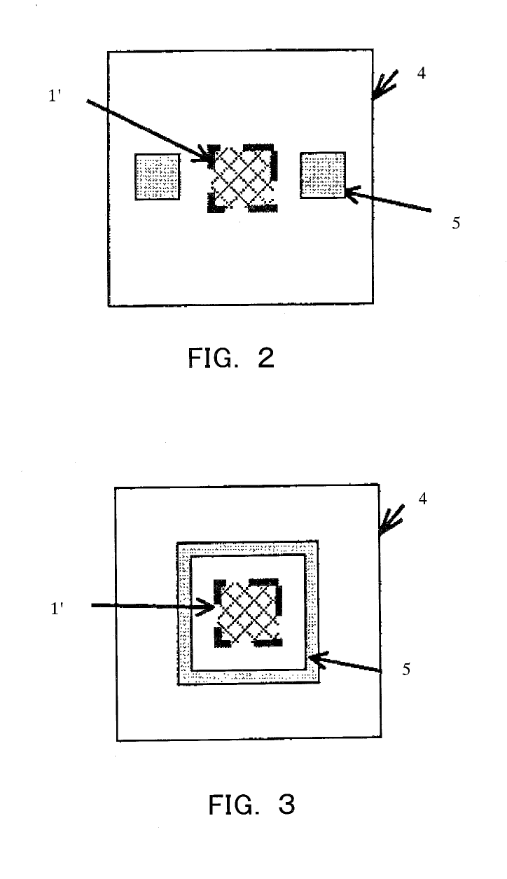

FIG. 2 is a plan view of the configuration within the housing 10 (a view from a direction shown by G in FIG. 1A) from the side of the support stages 5 of a direction in which the substrate 2, the heat-generating element 1, and the heat-radiating plate 4 are placed one on another. In FIG. 2, reference numeral 1′ shows an area from the housing front-wall 10a to the heat-radiating plate 4 that is overlaid with the heat-generating element 1 when viewed from the G direction, that is, an area in which the heat-generating element 1 is present when the heat-radiating plate 4 is viewed transparently from the G direction. The area 1′ will hereinafter be referred to as a heat-generating-element-placed area.

The support stages 5 are disposed outside the heat-generating-element-placed area 1′. Embodiment 1 has the two support stages 5 spaced from each other and sandwiching the area 1′ between them outside the heat-generating-element-placed area 1′. Each of the support stages 5 has a cubic shape or a rectangular parallelepiped shape (including a plate shape). While Embodiment 1 is described in conjunction with the two support stages 5, the number of the support stages 5 is not limited thereto in the present invention, and three or more support stages may be disposed outside the heat-generating-element-placed area with space between them.

Alternatively, as shown in FIG. 3, the support stage 5 may be formed in a rectangular frame shape and disposed outside the heat-generating-element-placed area 1′. In other words, the support stage 5 may be placed to surround the heat-generating-element-placed area 1′.

The shapes and arrangements of the support stages 5 shown in FIGS. 2 and 3 are merely illustrative, and any shape and arrangement of the support stages may be used in the present invention as long as the air layer 6 may be ensured between the heat-radiating plate 4 and the housing front-wall 10a. As described above, however, the placement of the support stages 5 outside the heat-generating-element-placed area 1′ can prevent the heat conducted from the heat-generating element 1 to the heat-radiating plate 4 from being readily conducted to the heat-generating-element-placed area 1′ via the support stages 5.

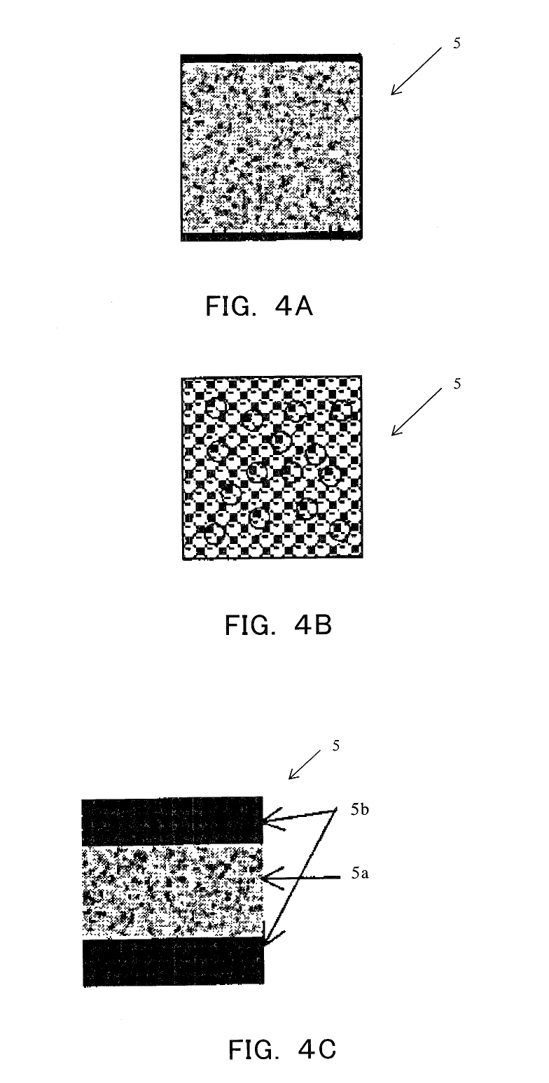

The support stages 5 are made of a generally used material with low thermal conductivity, for example, a fibrous material shown in FIG. 4A, a foam material shown in FIG. 4B, or a stacked material shown in FIG. 4C. The fibrous material includes glass wool (with a thermal conductivity of 0.034 W/mK), for example. The foam material includes, for example, extruded foam polystyrene (with a thermal conductivity of 0.038 W/mK) or foam polyethylene (with a thermal conductivity of 0.035 W/mK). The stacked material includes a typical heat-insulating material 5a sandwiched between elastic materials 5b such as urethane as shown in FIG. 4C, for example.

In this manner, the support stages 5 are preferably formed by using a material with lower thermal conductivity than that of plastic or metal. This can prevent the heat conducted from the heat-generating element 1 to the heat-radiating plate 4 from being easily conducted to the housing front-wall 10a via the support stages 5.

The support stages 5 can be made of the stacked material including the heat-insulating material sandwiched between the elastic materials as shown in FIG. 4C or other materials having elasticity to bring the heat-radiating plate 4 into press contact with the heat-generating element 1 more tightly by the elastic force of the elastic member as shown by an arrow J of a dotted line in FIG. 1B. This can reduce the thermal resistance from the heat-generating element 1 to the heat-radiating plate 4 to enhance the cooling effect for the heat-generating element 1 with the heat-radiating plate 4.

The air forming the air layer 6 has a thermal conductivity of 0.026 W/mK at temperatures from 60 to 90° C. and the thermal conductivity is equal to or lower than that of a typical heat-insulating member (with a thermal conductivity of 0.026 W/mK or higher). When a heat-insulating member is placed between the heat-radiating plate and the housing and is in contact with the abovementioned heat-generating-element-placed area as in the related art, heat not blocked by the heat-insulating member is conducted directly to the housing via the heat-insulating member to form a heat spot in the heat-generating-element-placed area of the housing at an extremely higher temperature than in the surroundings.

However, the formation of the air layer 6 between the heat-radiating plate 4 and the housing front-wall 10a as in Embodiment 1 prevents the heat from being readily conducted to the housing as compared with the case where the heat-insulating member is placed in contact with the housing, thereby enhancing the heat-insulating effect. It is thus possible to avoid the formation of a heat spot in the housing 10.

In addition, the air layer 6 is provided by using the small support stages 5, rather than the heat-insulating member having the large size equivalent to the heat-radiating plate 4, so that the weight of the portable electronic apparatus 100 can be reduced.

The heat-radiating plate 4 is not in contact with the housing 10, and (the entire outer periphery of) the air layer 6 is opened to space other than the air layer 6 in the housing 10. The heat conducted to the air layer 6 from the heat-radiating plate 4 can be diffused into the space other than the air layer 6 in the housing 10. Thus, the formation of a heat spot in the housing front-wall 10a can be avoided more efficiently.

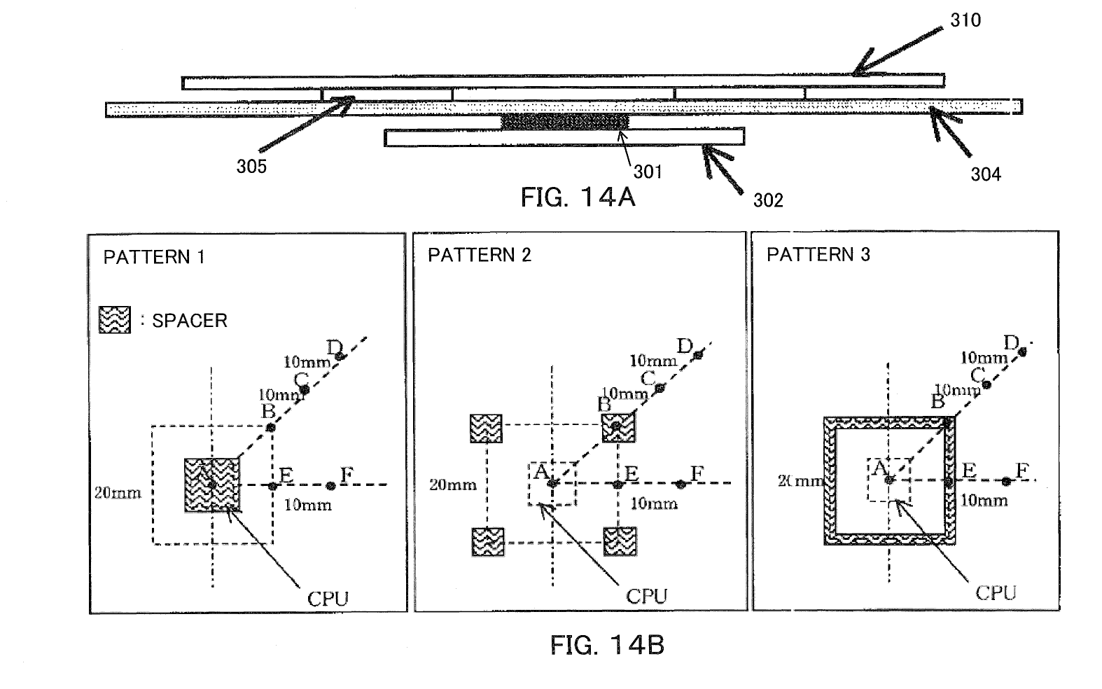

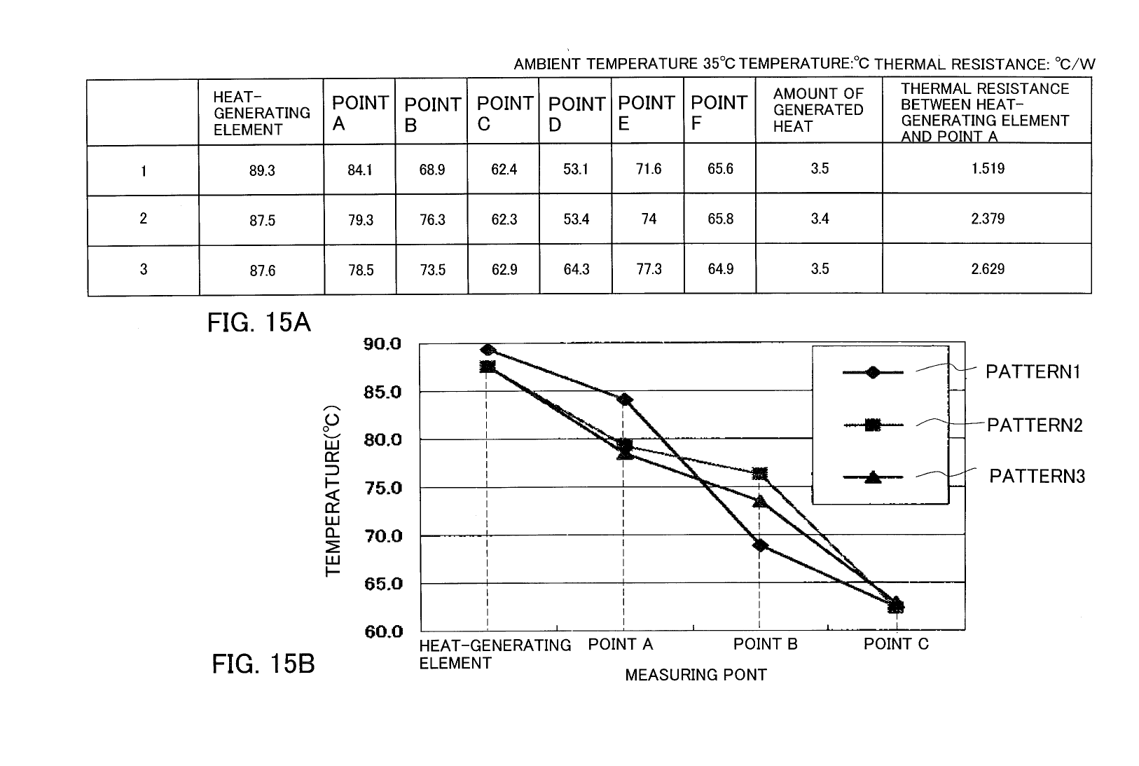

FIGS. 14(A), 14(B), 15(A), and 15(B) show the details of an experiment for studying the relationship between the arrangement and shape of the support stages and the temperature of the housing and the results of the experiment when the air layer is formed by the support stages between the heat-radiating plate and the housing.

In the experiment, as shown in FIG. 14(A), a support stage 305 made of a fibrous material (0.034 W/mK), a heat-radiating plate 304 formed of a copper plate (385 W/mK), a heat-generating element 301 having a box shape 10 millimeters square, and a substrate 302 were placed in order from the side of a housing 310 (corresponding to the housing front-wall 101a in FIG. 1A).

In a pattern 1 shown in FIG. 14(B), the support stage having a box shape 12 millimeters square was disposed to overlie a heat-generating-element-placed area 301′ in a plan view as in FIGS. 2 and 3, and the temperature of the housing 310 was measured at points A to F. The point A is at the center of the heat-generating-element-placed area 301′, the point B is spaced approximately 14 mm from the point A in a diagonal direction of the support stage, and the points C and D are spaced 10 mm and 20 mm from the point B, respectively, in the diagonal direction. The point E is spaced 10 mm from the point A in a direction in parallel with two opposite sides of the support stage. The point F is spaced from 10 mm from the point E in the parallel direction.

The pattern 1 is equivalent to the case where the heat-insulating member is disposed between the heat-radiating plate and the housing and is in contact with the housing including the point A.

In a pattern 2, four support stages having a box shape six millimeters square were arranged at corners of a box shape 20 millimeters square around the heat-generating-element-placed area 301′ outside the area 301′, and the temperature of the housing 301 was measured at points A to F. The positions of the points A to F are the same as those in the pattern 1.

In a pattern 3, a support stage having a frame shape 20 millimeters square was disposed to surround the heat-generating-element-placed area 301′ outside the area 301′, and the temperature of the housing 301 was measured at points A to F. The positions of the points A to F are the same as those in the pattern 1. Among the patterns 1 to 3, the support stages and the air layers had the same thicknesses (heights of the support stages 305, the heat-radiating plates 304, the heat-generating elements 301, and the substrates 302 in the overlying direction).

FIG. 15(A) shows temperatures (° C.) at the points A to F in the patterns 1 to 3 measured at an ambient temperature of 35° C. FIG. 15(A) also shows the temperature (° C.) of the heat-generating element 1, the amount of generated heat (consumed power) (W) of the heat-generating element 301, and the thermal resistance value (° C./W) between the heat-generating element 301 and the point A. FIG. 15(B) shows the temperatures of the heat-generating element 301 and temperature changes from the point A to point C in the patterns 1 to 3.

The temperatures of the housing at the point A in the patterns 2 and 3 were lower by approximately 5° C. than that in the pattern 1. The temperatures at the point B in the patterns 2 and 3 were higher than the temperature at the point B in the pattern 1 due to the contact with the support stage 305. Similarly, the temperature at the point E in the pattern 3 was higher than the temperature at the point B in the pattern 1 due to the contact with the support stage 305. However, the temperatures at the point B in the patterns 2 and 3 and at the point E in the pattern 3 were lower than the temperatures at the point A in the patterns 2 and 3.

The thermal resistance value between the heat-generating element 301 and the point A in the pattern 2 was approximately 1.56 times higher than that in the pattern 1, and in the pattern 3 it was approximately 1.73 times higher than that in the pattern 1.

As apparent from the experimental results, the arrangements of the support stages in the patterns 2 and 3 cause a higher temperature at the position of the housing in contact with the support stage as compared with the case where it is not in contact, but bring about a lower temperature at the point A corresponding to the heat spot in the pattern 1, which shows that the heat spot can be eliminated. In other words, the formation of a heat spot can be avoided in a wide range including the point A to the point F, and it is thus possible to prevent a user from touching a heat spot and feeling uncomfortable as in the pattern 1.

### Embodiment 2

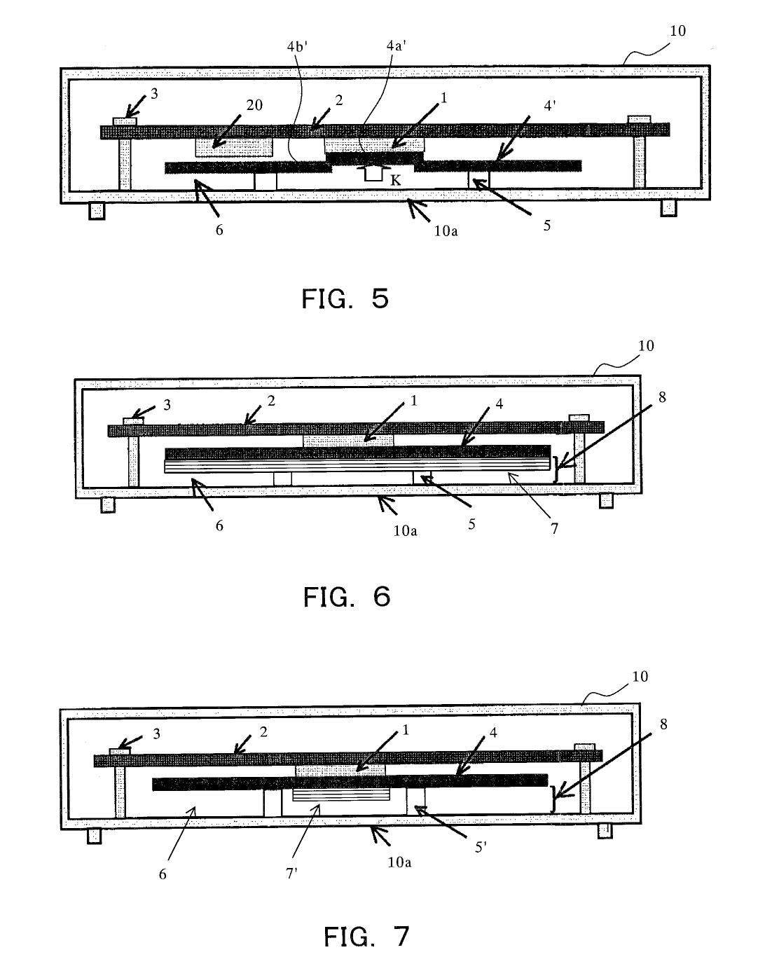

FIG. 5 shows the configuration within a housing 10 forming a first body portion of a portable electronic apparatus which is Embodiment 2 of the present invention. In Embodiment 2, components identical to those in Embodiment 1 are designated with the same reference numerals as those in Embodiment 1 to substitute for description.

Embodiment 2 employs a shape in which a portion 4a′ of a heat-radiating plate 4′ that overlies a heat-generating element 1 is protruded from a peripheral portion (remaining portion) 4b′ toward a substrate 2. Specifically, the portion of the heat-radiating plate 4′ that is in contact with the heat-generating element 1 has a convex shape and the opposite side thereof has a concave shape.

When the heat-radiating plate 4′ is made of a material having elasticity, the heat-radiating plate 4′ is formed in such a shape to allow enhanced adhesion between the protruded portion 4a′ and the heat-generating element 1 by elastic force K produced in the heat-radiating plate 4′ toward the substrate 2. This can reduce thermal resistance from the heat-generating element 1 to the heat-radiating plate 4′ to cool the heat-generating element 1 more efficiently.

In addition, in Embodiment 2, a thicker space can be provided between the peripheral portion 4b′ of the heat-radiating plate 4′ and the substrate 2 as compared with Embodiment 1. The space can be used to mount another large electronic component (such as an IC) 20 on a surface of the substrate 2 closer to the heat-radiating plate 4′ (surface on which the heat-generating element 1 is mounted). As a result, it is possible to reduce the thickness and size of a housing 10 (and thus the portable electronic apparatus) as compared with the case where the electronic component 20 is mounted on a surface of the substrate 2 opposed to the heat-radiating plate 4′.

### Embodiment 3

FIG. 6 shows the configuration within a housing 10 forming a first body portion of a portable electronic apparatus which is Embodiment 3 of the present invention. In Embodiment 3, components identical to those in Embodiment 1 are designated with the same reference numerals as those in Embodiment 1 to substitute for description.

Embodiment 3 includes a heat-insulating member (heat-insulating plate) 7 of a plate shape having substantially the same size as that of a heat-radiating plate 4 in an in-plate direction such that the heat-insulating member 7 is in contact with a surface of the heat-radiating plate 4 closer to a housing front-wall 10a, and support stages 5 are placed between the heat-insulating member 7 and the housing front-wall 10a to provide an air layer 6. In other words, in Embodiment 3, the support stages 5 (air layer 6), the heat-insulating member 7, the heat-radiating plate 4, a heat-generating element 1, and a substrate 2 are arranged in the housing 10 in the order from the side of the housing front-wall 10a. The heat-insulating member 7 and the air layer 6 form a heat-insulating layer 8 between the heat-radiating plate 4 and the housing front-wall 10a.

Embodiment 3 is effective particularly when the amount of heat generated by the heat-generating element 1 is larger than that of the heat-generating element 1 in Embodiment 1.

The heat-insulating member 7 is formed of a typical heat-insulating member having a thermal conductivity (0.026 W/mK or higher) equal to or higher than the thermal conductivity of air in the air layer 6 (0.024 to 0.026 W/mK), for example, foam urethane and silicon foam. Embodiment 3 can provide a higher heat-insulating effect to avoid formation of a heat spot in the housing as compared with the case where the heat-insulating member is in contact with the housing. The air layer 6 achieves the high heat-insulating effect even when a typical heat-insulating member is used, so that formation of a heat spot can be prevented. When the heat-insulating member is in contact with the housing as in the related art, it is contemplated that formation of a heat spot can also be avoided by increasing the thickness of the heat-insulating member. However, when the air layer is provided as in Embodiment 3, the thickness of the air layer necessary for avoiding the formation of a heat spot is smaller than the increased thickness of the heat-insulating member in the former case. Thus, the provision of the air layer can reduce the thickness from the substrate 2 to the housing front-wall 10a as compared with the case where the thickness of the heat-insulating member is increased. As a result, the housing 10 (and thus the portable electronic apparatus) can be reduced in size while the formation of a heat spot in the housing front-wall 10a is avoided. The heat-radiating plate 4 and the heat-insulating member 7 are not in contact with the housing 10, and the air layer 6 is opened to space other than the air layer 6 in the housing 10. This causes the heat conducted to the air layer 6 from the heat-insulating member 7 to be diffused into the air layer 6 and the space other than the air layer 6 in the housing 10, thereby avoiding formation of a heat spot in the housing front-wall 10a more effectively.

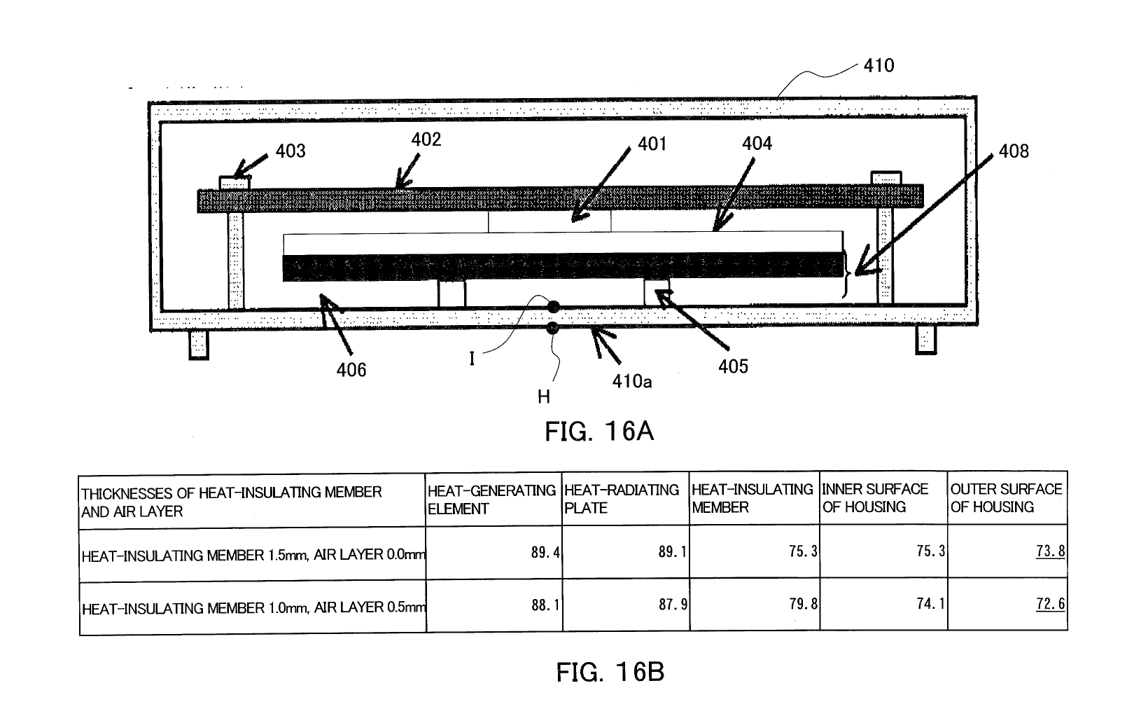

FIG. 16(B) shows the results of an experiment performed to compare the temperatures of the housing when the heat-insulating member is increased in thickness to be contact with the housing (when the air layer is not provided) and when the air layer is provided.

FIG. 16(A) shows an experimental apparatus including an air layer 406 provided between a heat-insulating member 407 and a housing front-wall 410a. When the air layer 406 was not provided, a different experimental apparatus was used in which the heat-insulating member 407 occupied the place where the air layer 406 otherwise would be located. As shown in FIG. 16(B), the thickness of the heat-insulating member 407 when the air layer 406 is not provided is 1.5 mm, and the thicknesses of the heat-insulating member 407 and the air layer 406 when the air layer 406 is provided are 1.0 mm and 0.5 mm, respectively. The housing 410 had outer dimensions of 110×260×14 mm and had a wall portion of a thickness of 1 mm.

The amount of heat generated by the heat-generating element 401 was 3.5 W. The heat-radiating plate 404 was formed by using a copper plate of 50×100 mm (385 W/mK). The heat-insulating member 407 had a thermal conductivity of 0.026 W/mK.

FIG. 16(B) shows the temperatures of the heat-generating element 401, the heat-radiating plate 404, the heat-insulating member 407, and centers I and H of a heat-generating-element-placed area on the inner surface and outer surface of the housing 410 (housing front-wall 410a), respectively, in both cases.

As apparent from FIG. 16(B), as compared with the case where the air layer is not provided and the heat-insulating member is thicker in 1.5 mm, the temperature of the outer surface of the housing was 1.2° C. lower when the heat-insulating member of 1.0 mm and the air layer 406 of 0.5 mm were formed in a heat-insulating layer 408 having the same thickness as that of the heat-insulating member of 1.5 mm in the former case. Thus, it can be seen that the air layer has a more excellent heat-insulating effect than that of the heat-insulating member, that is, an effect of avoiding formation of a heat spot. In addition, it can be seen that the air layer 6 (support stage 5) of at least half of the thickness of the heat-insulating member 4 is formed to provide an effect of reducing the temperature of the outer surface of the housing as compared with the case where the heat-insulating member is increased in thickness by the same amount.

When the air layer is not provided, it can be assumed that the heat-insulating member needs to be thicker than 1.5 mm in order to reduce the temperature of the outer surface of the housing to a temperature similar to that when the air layer 406 is provided.

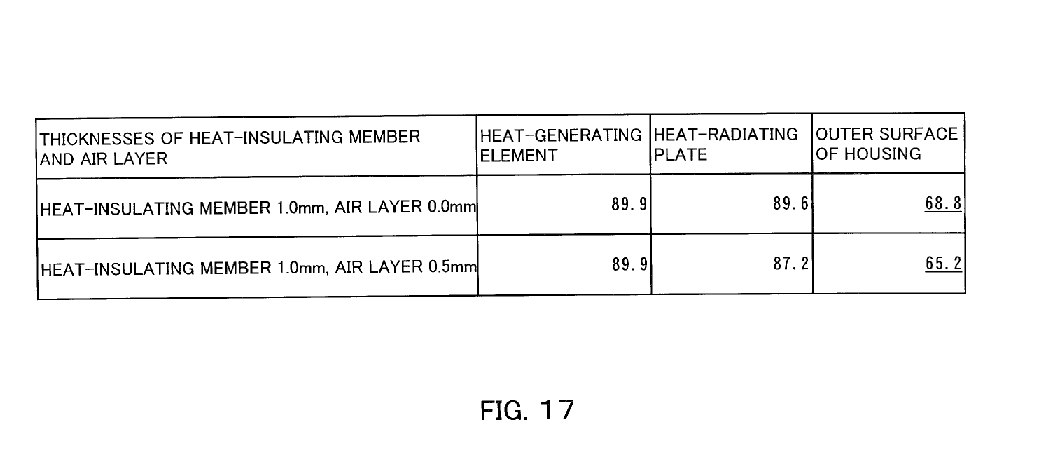

FIG. 17 shows the results of an experiment performed to compare the temperatures of the housing when the air layer is not provided and when the air layer is provided in the case of using the heat-insulating member having the same thickness. In the experiment, the thickness of the heat-insulating member was 1.0 mm, the amount of heat generated by the heat-generating element was 5 W, and the heat-radiating plate was formed by using a graphite sheet (240 W/mK). In the experiment, the heat-insulating member had a thermal conductivity (0.005 W/mK) lower than that of air. The other conditions in the experiment are identical to those in FIGS. 16(A) and 16(B).

As apparent from FIG. 17, the temperature of the outer surface of the housing was 3.6° C. lower when the air layer was provided than when the air layer was not provided. This shows that the provision of the air layer can reduce the temperature of the housing (avoid formation of a heat spot more reliably) as compared with the case where the air layer was not provided.

While Embodiment 3 has been described in conjunction with the case where the heat-insulating member 7 and the support stage 5 are formed as separate components, it is possible that part of the heat-insulating member 7 is formed in a shape protruded toward the housing front-wall 10a and is used as a support stage. In this case, a plate-shaped portion of the heat-insulating member that extends along the heat-radiating plate corresponds to a “heat-insulating member” in claim 1, while the portion of the support-stage shape corresponds to a “support stage.” This applies to other embodiments, later described, in which the heat-insulating member is used.

### Embodiment 4

FIG. 7 shows the configuration within a housing 10 forming a first body portion of a portable electronic apparatus which is Embodiment 4 of the present invention. In Embodiment 4, components identical to those in Embodiment 1 are designated with the same reference numerals as those in Embodiment 1 to substitute for description.

Embodiment 4 includes a heat-insulating member 7′ provided only in an area of a surface of a heat-radiating plate 4 closer to a housing front-wall 10a in Embodiment 1 that generally overlies a heat-generating element 1 when viewed from a direction in which the heat-generating element 1 and the heat-radiating plate 4 are placed one on another. The heat-insulating member 7′ has a size slightly larger than that of the heat-generating element 1 in an in-plane direction.

An air layer 6 is formed in an area of the heat-radiating plate 4 that is not overlaid with the heat-insulating member 7′ and between the heat-insulating member 7′ and the housing front-wall 10a. Embodiment 4 is effective particularly when the amount of heat generated by the heat-generating element 1 is larger than that in Embodiment 1.

As in Embodiment 1, the air layer 6 is opened to space other than the air layer 6 in the housing 10. Support stages 5 are placed between the area of the heat-radiating plate 4 that is not overlaid with the heat-insulating member 7′ and the housing front-wall 10a.

According to Embodiment 4, a high heat-insulating effect of the heat-insulating member 7′ provided in the area generally overlying the heat-generating element 1 and the air layer 6 can avoid formation of a heat spot in the housing front-wall 10a. In addition, the portable electronic apparatus can be reduced in weight as compared with the case where the size of the heat-insulating member 7′ is substantially the same as that of the heat-radiating plate 4 as in Embodiment 2.

### Embodiment 5

FIG. 8 shows the configuration within a housing 10 forming a first body portion of a portable electronic apparatus which is Embodiment 5 of the present invention. In Embodiment 5, components identical to those in Embodiment 3 are designated with the same reference numerals as those in Embodiment 3 to substitute for description.

In Embodiment 5, in the configuration of Embodiment 3, a portion 4a′ of a heat-radiating plate 4′ that overlies a heat-generating element 1 has a shape protruded away from a housing front-wall 10a from a peripheral portion (remaining portion) 4b′ as in Embodiment 2. When the heat-radiating plate 4′ is made of a material having elasticity, the elastic force can increase adhesion between the protruded portion 4a′ and the heat-generating element 1 to reduce thermal resistance from the heat-generating element 1 to the heat-radiating plate 4′. Thus, the heat-generating element 1 can be cooled more efficiently.

In Embodiment 5, a thicker space can be formed between the peripheral portion 4b′ of the heat-radiating plate 4′ and a substrate 2 as compared with Embodiment 1. The space can be used to mount another large electronic component (such as an IC) 20 on a surface of the substrate 2 closer to the heat-radiating plate 4′ (surface on which the heat-generating element 1 is mounted). As a result, it is possible to reduce the thickness and size of a housing 10 (and thus the portable electronic apparatus) as compared with the case where the electronic component 20 is mounted on a surface of the substrate 2 not opposed to the heat-radiating plate 4′.

### Embodiment 6

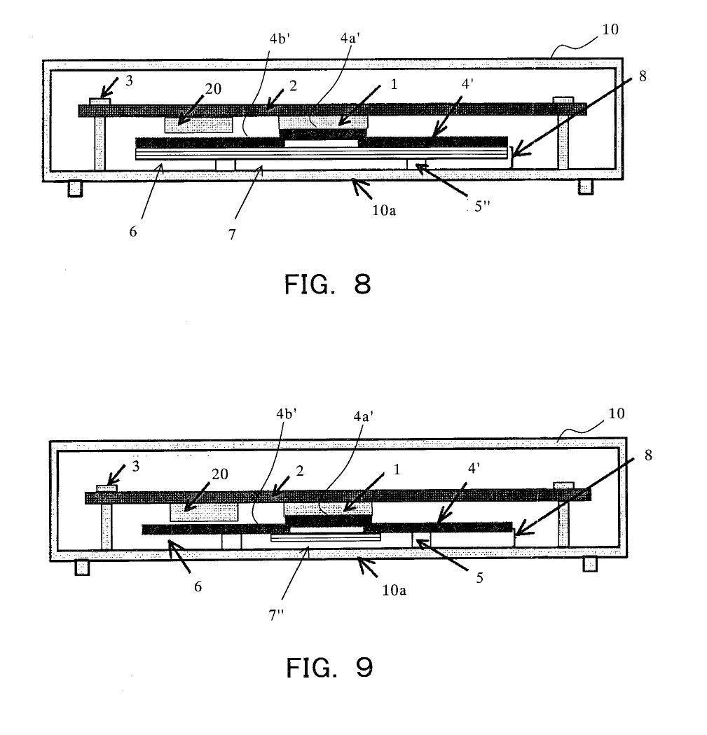

FIG. 9 shows the configuration within a housing 10 forming a first body portion of a portable electronic apparatus which is Embodiment 6 of the present invention. In Embodiment 6, components identical to those in Embodiment 5 are designated with the same reference numerals as those in Embodiment 5 to substitute for description.

In Embodiment 6, a heat-insulating member 7″ having a size slightly larger than that of a heat-generating element 1 in an in-plane direction is provided in an area of a surface of a heat-radiating plate 4′ closer to a housing front-wall 10a that is opposed to a protruded portion 4a′ in contact with (overlying) the heat-generating element 1.

This can achieve a high heat-insulating effect of the heat-insulating member 7″ provided in the area of the heat-radiating plate 4′ that generally overlies the heat-generating element 1 and an air layer 6, in addition to the effect described in Embodiment 5, to avoid formation of a heat spot more reliably in a heat-generating-element-placed area (see FIGS. 2 and 3) of the housing front-wall 10a. Furthermore, the portable electronic apparatus can be reduced in weight as compared with the case where the size of the heat-insulating member 7″ is substantially the same as that of the heat-radiating plate 4′ as in Embodiment 4.

### Embodiment 7

FIG. 10 shows the configuration within a housing 10 forming a first body portion of a portable electronic apparatus which is Embodiment 7 of the present invention. In Embodiment 7, components identical to those in Embodiment 3 are designated with the same reference numerals as those in Embodiment 3 to substitute for description.

In Embodiment 7, in addition to the configuration of Embodiment 3, a heat spreader 9 having a size larger than that of a heat-generating element 1 in an in-plane direction is placed between the heat-generating element 1 and a heat-radiating plate 4. The heat spreader 9 is made of metal having high thermal conductivity and conducts heat from the heat-generating element 1 in the in-plane direction with high thermal conductivity. This can conduct the heat from the heat-generating element 1 to the heat-radiating plate 4 through a wider area as compared with the case where the heat-generating element 1 is in direct contact with the heat-radiating plate 4. Thus, more heat can be conducted in the in-plane direction of the heat-radiating plate 4 to achieve efficient heat radiation with the heat-radiating plate 4.

The addition of the heat spreader 9 elongates the heat conducting path from the heat-generating element 1 to a housing front-wall 10a than in Embodiment 3. This can reduce the temperature of a heat-generating-element-placed area 1′ (see FIGS. 2 and 3) of the housing front-wall 10a.

Embodiment 7 is effective particularly when the heat-generating element 1 is small (when the area thereof in contact with the heat-radiating plate 4 is small) or when the heat-radiating plate 4 is made of a graphite sheet or the like having low thermal conductivity in a thickness direction.

### Embodiment 8

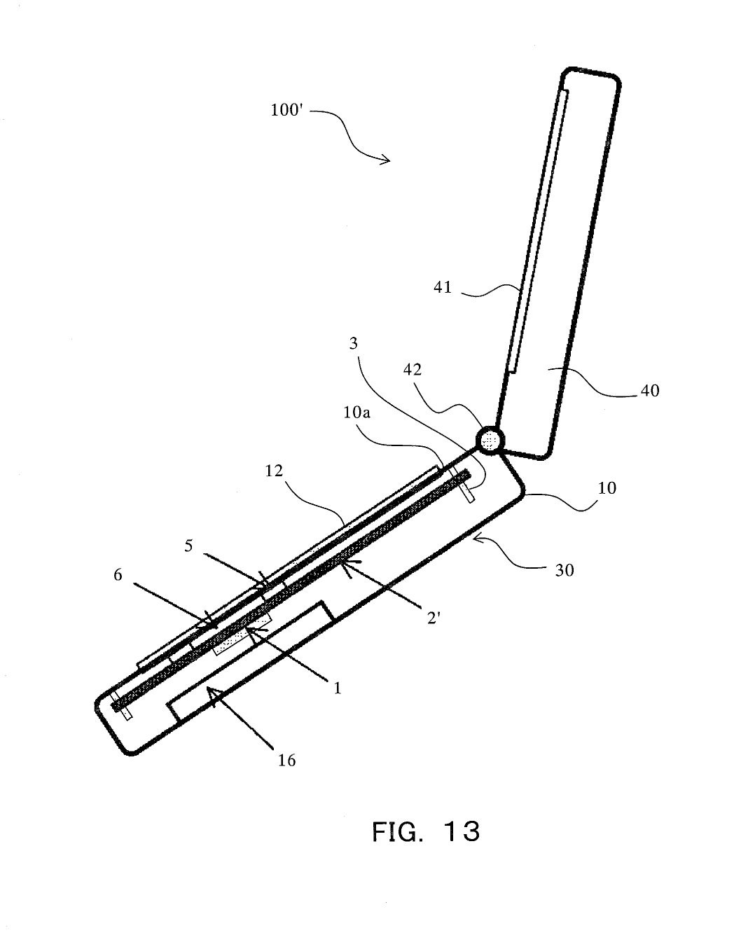

FIG. 13 schematically shows the configuration of a portable electronic apparatus 100′ which is Embodiment 8 of the present invention. In Embodiment 8, components identical to those of the portable electronic apparatus 100 described in Embodiment 1 (FIG. 12) are designated with the same reference numerals as those in Embodiment 1 to substitute for description.

In Embodiment 8, a heat-radiating plate 4 separate from a substrate 2 described in Embodiment 1 is not placed within a housing 10 forming a first body portion 30, and a substrate 2′ itself serves as a heat-radiating plate by forming the substrate 2′ of a material with high thermal conductivity such as aluminum nitride or by using a configuration appropriate for heat radiation.

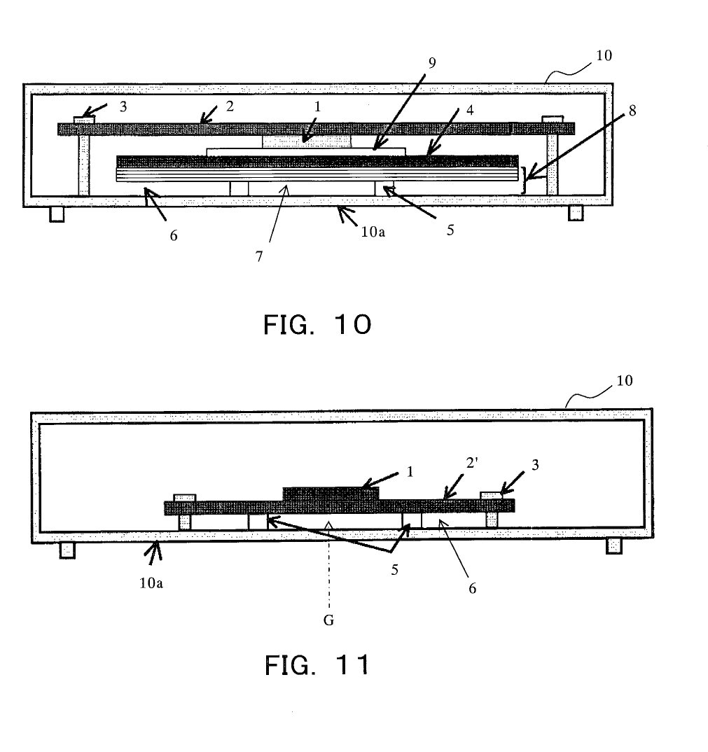

FIG. 11 is an enlarged view showing the configuration within the housing 10. In FIG. 11, the substrate 2′ is fixed to a housing front-wall 10a by screws 3 at both ends on the left and right. A heat-generating element 1 is mounted on a surface of the substrate 2′ not opposed to the housing front-wall 10a.

Support stages 5 are placed between the substrate 2′ and the housing front-wall 10a to form an air layer 6 having a predetermined thickness between the substrate 2′ and the housing front-wall 10a. In other words, in Embodiment 8, the support stages 5 (air layer 6), the substrate 2, and the heat-generating element 1 are arranged in the order from the side of the housing front-wall 10a.

In Embodiment 8, the support stages 5 are sandwiched and fixed between the housing front-wall 10a and the substrate 2′ subjected to the securing force from the screws 3. The support stages 5 have the function of placing the substrate 2′ spaced from the housing front-wall 10a against the securing force to ensure the air layer 6 having the predetermined thickness. The support stages 5 may be fixed to the housing front-wall 10a or the substrate 2′ through bonding or a tape.

The support stages 5 are disposed outside a heat-generating-element-placed area as described in Embodiment 1 when viewed from the side of the support stages 5 of a direction in which the heat-generating element 1 and the substrate 2′ are disposed one on another, as shown by G in FIG. 11. Specifically, the support stages 5 having the shape as shown in FIG. 2 or 3, for example, are disposed outside the heat-generating-element-placed area 1′ shown in FIG. 2 or 3.

The support stages 5 are preferably made of a fibrous material (FIG. 4A), a foam material (FIG. 4B), or a stacked material (FIG. 4C) as shown in Embodiment 1. This can prevent heat conducted from the heat-generating element 1 to the substrate 2′ from being easily conducted to the housing front-wall 10a through the support stages 5.

In Embodiment 8, the formation of the air layer 6 between the substrate 2′ and the housing front-wall 10a can make it more difficult to conduct heat to the housing 10 as compared with the case where a heat-insulating member placed between the substrate 2′ and the housing front-wall 10a is in contact with the housing front-wall 10a. For this reason, formation of a heat spot in the housing front-wall 10a can be avoided.

In addition, the air layer 6 is provided by using the small support stages 5, rather than the heat-insulating member having the large size equivalent to the substrate 2′, so that the weight of the portable electronic apparatus 100′ can be reduced.

The substrate 2′ is not in contact with the housing 10, and the air layer 6 is opened to space other than the air layer 6 in the housing 10. The heat conducted to the air in the air layer 6 from the substrate 2′ can be diffused into the space other than the air layer 6 in the housing 10. Thus, the formation of a heat spot can be avoided more efficiently.

Furthermore, since the substrate 2′ serves as the heat-radiating plate to eliminate the need for a heat-radiating plate different from the substrate 2′, Embodiment 8 is effective in reducing the thickness, size, and weight of the portable electronic apparatus 100′.

### Embodiment 9

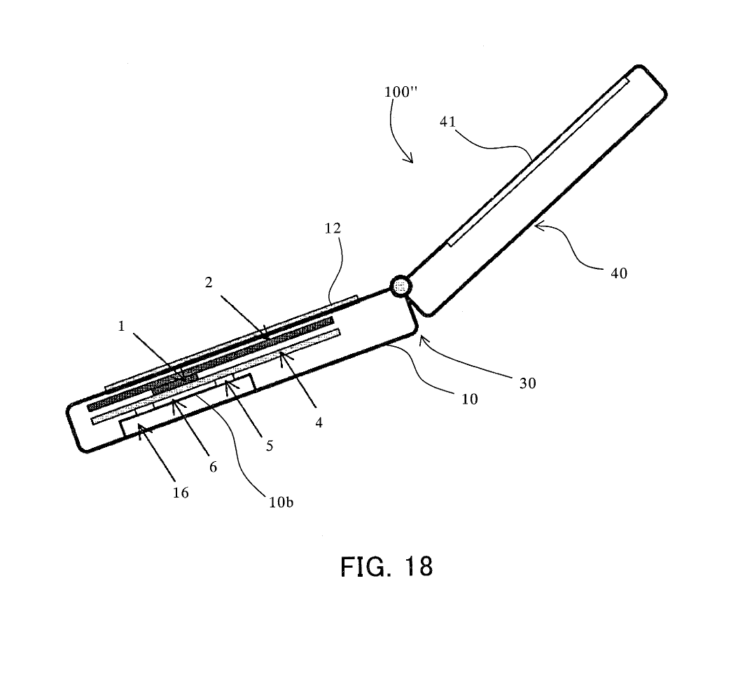

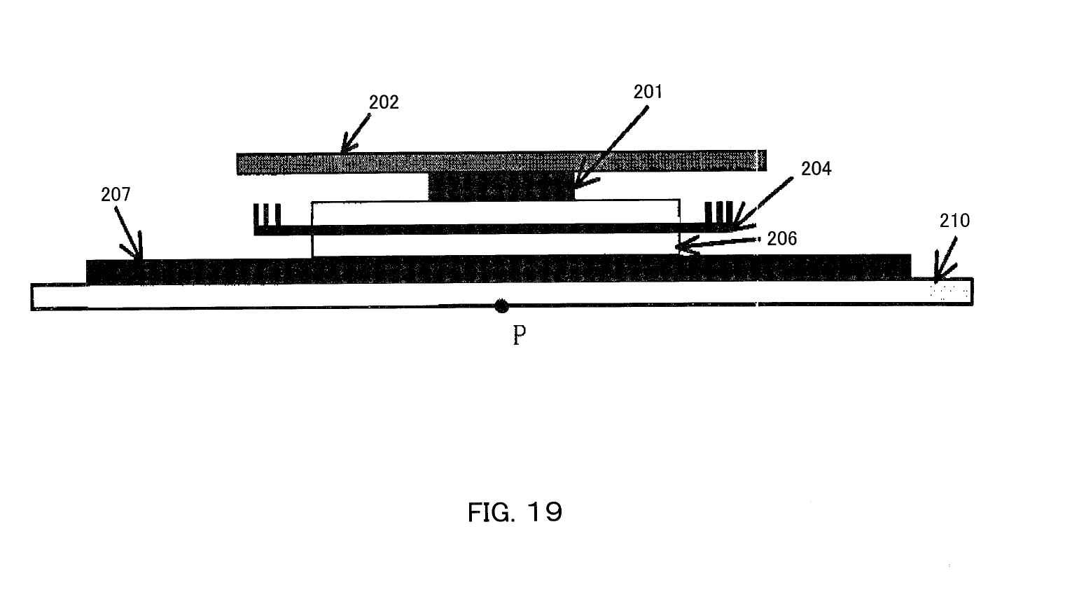

FIG. 18 schematically shows the configuration of a portable electronic apparatus 100″ which is Embodiment 9 of the present invention. In Embodiment 9, components identical to those of the portable electronic apparatus 100 described in Embodiment 1 (FIG. 12) are designated with the same reference numerals as those in Embodiment 1 to substitute for description.

Embodiment 1 has been described in conjunction with the configuration for preventing formation of a heat spot in the wall portion (housing front-wall 10a) of the first body portion 30 (housing 10) closer to the operation portion 12 by heat generated in the heat-generating element 1.

In contrast, Embodiment 9 is provided to prevent formation of a heat spot in a housing rear-wall 10b which is a wall portion of a housing 10 closer to a battery 16 by heat generated in a heat-generating element 1. Specifically, support stages 5 (air layer 6), a heat-radiating plate 4, the heat-generating element 1, and a substrate 2 are arranged within the housing 10 in the order from the housing rear-wall 10b.

A heat spot formed in the housing rear-wall 10b heats the battery 16 and increases the temperature of a cover (part of the housing) over the battery 16. The cover portion is often touched by a user with his hand when he holds the portable electronic apparatus 100″, so that an increased temperature in that portion may cause user discomfort. However, it is possible to reduce an increase in temperature of the battery 16 and the cover over the battery 16 by avoiding the formation of a heat spot in the housing rear-wall 10b with Embodiment 9.

As described above, according to each of Embodiments 1 to 9, since the heat-insulating effect of the air layer prevents the heat from being easily conducted to the first wall portion of the housing, the formation of a heat spot in the first wall portion can be avoided even when the heat-generating element which generates a large amount of heat is used.

While preferred embodiments of the present invention have been described, the present invention is not limited thereto and various modifications and variations are possible. For example, the materials of the heat-radiating plate, the heat-insulating member, and the support stage are not limited to those described in Embodiments 1 to 9. Also, the present invention is widely applicable to electronic apparatuses such as cellular phones, notebook personal computers (PC), and digital cameras.

The present invention is effective as a cooling configuration for a heat-generating element in an electronic apparatus such as a cellular phone, a notebook personal computer, and a digital camera, and especially appropriate for cooling to avoid formation of a heat spot in a housing.

What is claimed is:

1. An electronic apparatus comprising:
a heat-generating element;
a heat-radiating plate which is used in heat radiation of the heat-generating element; and
a housing which accommodates the heat-generating element and the heat-radiating plate,
wherein the heat-radiating plate is disposed between the heat-generating element and a first wall portion of the housing,
the electronic apparatus further comprising a support stage for forming an air layer between the heat-radiating plate and the first wall portion.

2. The electronic apparatus according to claim 1, further comprising a heat-insulating member placed closer to the first wall portion than the heat-radiating plate, wherein the air layer is formed between the heat-insulating member and the first wall portion.

3. The electronic apparatus according to claim 2, wherein the air layer has a thickness of at least half of a thickness of the heat-insulating member.

4. The electronic apparatus according to claim 1, wherein the air layer is opened to space other than the air layer in the housing.

5. The electronic apparatus according to claim 1, wherein a portion of the heat-radiating plate, which is in contact with the heat-generating element, is protruded toward the heat-generating element from a remaining portion of the heat-radiating plate.

6. The electronic apparatus according to claim 5, further comprising an electronic component different from the heat-generating element and disposed between the remaining portion and a substrate on which the heat-generating element is mounted.

7. The electronic apparatus according to claim 5, wherein the heat-radiating plate has elasticity and the portion thereof protruded toward the heat-generating element is in press contact with the heat-generating element by elastic force.

8. The electronic apparatus according to claim 1, wherein the support stage is formed of a fibrous material, a foam material, or a stacked material including a heat-insulating member therein.

9. The electronic apparatus according to claim 1, wherein the support stage is disposed outside an area where the heat-generating element is placed when viewed from a direction in which the heat-generating element and the heat-radiating plate are disposed one on another.

10. The electronic apparatus according to claim 1, wherein the support stage has elasticity and brings the heat-radiating plate into press contact with the heat-generating element by elastic force.

11. The electronic apparatus according to claim 1, further comprising a heat spreader having a size larger than that of the heat-generating element and placed between the heat-generating element and the heat-radiating plate.

12. The electronic apparatus according to claim 1, wherein the heat-radiating plate is a substrate on which the heat-generating element is mounted.

13. The electronic apparatus according to claim 1, further comprising an operation member operated by a user and placed in the first wall portion.
